(19) United States
(12) Patent Application Publication
(10) Pub. No.: US 2019/0096928 A1
(43) Pub. Date: Mar. 28, 2019

(54) ULTRAVIOLET LIGHT RECEIVING ELEMENT AND METHOD OF MANUFACTURING ULTRAVIOLET LIGHT RECEIVING ELEMENT

(71) Applicant: ABLIC Inc., Chiba-shi (JP)

(72) Inventors: Kazusa OKUDA, Chiba-shi (JP); Toshiro FUTATSUGI, Chiba-shi (JP)

(21) Appl. No.: 16/139,360

(22) Filed: Sep. 24, 2018

(30) Foreign Application Priority Data
Sep. 25, 2017 (JP) 2017-183963

(51) Int. Cl. H01L 27/144; H01L 31/102; H01L 31/101; G01J 1/42

(52) U.S. Cl. CPC H01L 27/1443; G01J 1/429; H01L 31/1013; H01L 31/102

(57) ABSTRACT

Provided is an ultraviolet light receiving element capable of reducing visible light sensitivity. The ultraviolet light receiving element includes: a first photodiode sensitive to an ultraviolet light provided in a first region of a semiconductor substrate; and a second photodiode insensitive to the ultraviolet light provided in a second region of the semiconductor substrate. A second well implantation layer in the second photodiode has a peak concentration position deeper than a peak concentration position of a well implantation layer in the first photodiode by a depth equal to a depth from a surface of the semiconductor substrate to a peak concentration position of a surface implantation layer in the second photodiode.

### RELATED APPLICATIONS

This application claims priority under 35 U.S.C. § 119 to Japanese Patent Application No. 2017-183963 filed on Sep. 25, 2017, the entire content of which is hereby incorporated by reference.

### BACKGROUND OF THE INVENTION

### 1. Field of the Invention

The present invention relates to an ultraviolet light receiving element and a method of manufacturing an ultraviolet light receiving element.

### 2. Description of the Related Art

Normally, sunlight irradiating the ground has a wide range wavelength distribution which includes ultraviolet light, visible light, and infrared light in a wavelength range from 300 nm to 2,500 nm. Of the sunlight described above, the ultraviolet light is known to have adverse effects on human body, such as sunburn and skin cancer.

In recent years, high expectations have been put on the development of a sensor capable of detecting the intensity of an ultraviolet light in order to measure effects of the ultraviolet light.

In order to give the light receiving element selective sensitivity to an ultraviolet light alone, there has been proposed an ultraviolet light receiving element which consists of a semiconductor light receiving element having a photodiode sensitive to an ultraviolet light and a photodiode insensitive to an ultraviolet light, and which is configured to calculate a difference between output currents obtained from each of the photodiodes to detect an ultraviolet light (see, for example, WO 2015/151198 A1 and Y. R. Sipauba Carvalho da Silva, et al., “An Ultraviolet Radiation Sensor Using Differential Spectral Response of Silicon Photodiodes”, 2015 IEEE SENSORS, pp. 1-4).

In this type of ultraviolet light receiving element of the related art, a semiconductor substrate is provided with two photodiodes, in each of which a shallow impurity implantation layer is formed on a surface of the semiconductor substrate in each well implantation layer. The peak concentration position from the surface of the semiconductor substrate is made difference between the impurity implantation layers of the two photodiodes, to thereby make one of the two photodiodes sensitive to the ultraviolet light and the other photodiode insensitive to the ultraviolet light.

In the ultraviolet light receiving element of the related art, the peak concentration position from the surface of the semiconductor substrate in the well implantation layer of the photodiode insensitive to the ultraviolet light is set equal to or deeper than the peak concentration position from the surface of the semiconductor substrate in the well implantation layer of the photodiode sensitive to the ultraviolet light.

However, there is no suggestion on how to determine the peak concentration position from the surface of the semiconductor substrate in the well implantation layer of the photodiode insensitive to the ultraviolet light in the ultraviolet light receiving element of the related art and, in some cases, spectral sensitivity in the visible light range increases when the peak concentration position of the photodiode insensitive to the ultraviolet light is simply set deeper than the peak concentration position from the surface of the semiconductor substrate in the well implantation layer of the photodiode sensitive to the ultraviolet light as described above.

### SUMMARY OF THE INVENTION

It is therefore an object of the present invention to provide an ultraviolet light receiving element capable of reducing spectral sensitivity in the visible light range and a method of manufacturing the ultraviolet light receiving element.

In one embodiment of the present invention, there is provided an ultraviolet light receiving element including: a first photodiode sensitive to an ultraviolet light provided in a first region of a semiconductor substrate, and including a first well implantation layer of a first conductivity type, a first embedded implantation layer of a second conductivity type, and a first surface implantation layer of the first conductivity type, the first embedded implantation layer being formed in the first well implantation layer, the first surface implantation layer being formed in a surface of the semiconductor substrate in the first embedded implantation layer; and a second photodiode insensitive to an ultraviolet light provided in a second region of the semiconductor substrate, and including a second well implantation layer of the first conductivity type, a second embedded implantation layer of the second conductivity type, and a second surface implantation layer of the first conductivity type, the second embedded implantation layer being formed in the second well implantation layer, the second surface implantation layer being formed in the surface of the semiconductor substrate in the second embedded implantation layer, wherein the second well implantation layer has a peak concentration position deeper than a peak concentration position of the first well implantation layer by a depth equal to a depth from the surface of the semiconductor substrate to a peak concentration position of the second surface implantation layer.

In another embodiment of the present invention, there is provided an ultraviolet light receiving element including: a first photodiode sensitive to the ultraviolet light provided in a first region of a semiconductor substrate, and including a first well implantation layer of a first conductivity type, a first embedded implantation layer of a second conductivity type, and a first surface implantation layer of the first conductivity type, the first embedded implantation layer being formed in the first well implantation layer, the first surface implantation layer being formed in a surface of the semiconductor substrate in the first embedded implantation layer; and a second photodiode insensitive to the ultraviolet light provided in a second region of the semiconductor substrate, and including a second well implantation layer of the first conductivity type, a second embedded implantation layer of the second conductivity type, and a second surface implantation layer of the first conductivity type, the second embedded implantation layer being formed in the second well implantation layer, the second surface implantation layer being formed in the surface of the semiconductor substrate in the second embedded implantation layer, wherein the second well implantation layer has a peak concentration position deeper than the peak concentration position of the first well implantation layer by a depth dₚ which is calculated by the following expression:

dₚ≈dₛ exp(αxₚ)

where dₛ is a depth from the surface of the semiconductor substrate to a peak concentration position of the second surface implantation layer, xₚ is a depth from the surface of the semiconductor substrate to a peak concentration position of the first well implantation layer, α is a light absorption coefficient in the semiconductor substrate, and αxₚ is not regarded as zero.

In still another embodiment of the present invention, there is provided a method of manufacturing an ultraviolet light receiving element including: forming, in a first region of a semiconductor substrate of a first conductivity type, a first photodiode sensitive to the ultraviolet light including a first well implantation layer of a second conductivity type, a first embedded implantation layer of the first conductivity type, and a first surface implantation layer of the second conductivity type, the first embedded implantation layer being formed in the first well implantation layer, the first surface implantation layer being formed in a surface of the semiconductor substrate in the first embedded implantation layer; and forming, in a second region of the semiconductor substrate, a second photodiode insensitive to the ultraviolet light including a second well implantation layer of the second conductivity type, a second embedded implantation layer of the first conductivity type, and a second surface implantation layer of the second conductivity type, the second embedded implantation layer being formed in the second well implantation layer, the second surface implantation layer being formed in the surface of the semiconductor substrate in the second embedded implantation layer, wherein the second well implantation layer is formed so as to have a peak concentration position deeper than a peak concentration position of the first well implantation layer by a depth equal to a depth from the surface of the semiconductor substrate to a peak concentration position of the second surface implantation layer.

In still another embodiment of the present invention, there is provided a method of manufacturing an ultraviolet light receiving element including: forming, in a first region of a semiconductor substrate of a first conductivity type, a first photodiode sensitive to an ultraviolet light including a first well implantation layer of a second conductivity type, a first embedded implantation layer of the first conductivity type, and a first surface implantation layer of the second conductivity type, the first embedded implantation layer being formed in the first well implantation layer, the first surface implantation layer being formed in a surface of the semiconductor substrate in the first embedded implantation layer; and forming, in a second region of the semiconductor substrate, a second photodiode insensitive to the ultraviolet light including a second well implantation layer of the second conductivity type, a second embedded implantation layer of the first conductivity type, and a second surface implantation layer of the second conductivity type, the second embedded implantation layer being formed in the second well implantation layer, the second surface implantation layer being formed in the surface of the semiconductor substrate in the second embedded implantation layer, wherein the second well implantation layer is formed so as to have a peak concentration position deeper than the peak concentration position of the first well implantation layer by a depth dₚ which is calculated by the following expression:

dₚ≈dₛ exp(αxₚ)

where dₛ is a depth from the surface of the semiconductor substrate to a peak concentration position of the second surface implantation layer, xₚ is a depth from the surface of the semiconductor substrate to a peak concentration position of the first well implantation layer, α is a light absorption coefficient in the semiconductor substrate, and αxₚ is not regarded as zero.

According to above embodiments of the present invention, visible light sensitivities can be substantially equalized in both of the photodiode sensitive to the ultraviolet light and the photodiode insensitive to the ultraviolet light. The ultraviolet light receiving element and the method of manufacturing the ultraviolet light receiving element capable of reducing spectral sensitivity in the visible light range can consequently be provided.

### BRIEF DESCRIPTION OF THE DRAWINGS

Embodiments of the invention will now be described, by way of example, with reference to the accompanying drawings, in which:

FIG. 1 is a sectional view for illustrating the configuration of an ultraviolet light receiving element according to a first embodiment of the present invention;

FIG. 2 is a graph for showing attenuation of the intensity of a light in depth direction when a single-crystal silicon substrate is used as a semiconductor substrate;

FIG. 3 is a sectional view for illustrating a manufacturing step in a method of manufacturing the ultraviolet light receiving element according to the first embodiment of the present invention;

FIG. 4 is a sectional view for illustrating a manufacturing step in the method of manufacturing the ultraviolet light receiving element according to the first embodiment of the present invention;

FIG. 5 is a sectional view for illustrating a manufacturing step in the method of manufacturing the ultraviolet light receiving element according to the first embodiment of the present invention;

FIG. 6 is a graph for showing spectral sensitivity characteristics in the ultraviolet light receiving element according to the first embodiment of the present invention, and spectral sensitivity characteristics observed when peak concentration positions of two well implantation layers are set to the same;

FIG. 7 is a sectional view for illustrating the configuration of an ultraviolet light receiving element according to a second embodiment of the present invention;

FIG. 8 is a sectional view for illustrating a manufacturing step in a method of manufacturing the ultraviolet light receiving element according to the second embodiment of the present invention;

FIG. 9 is a sectional view for illustrating the manufacturing step in a method of manufacturing the ultraviolet light receiving element according to the second embodiment of the present invention; and

FIG. 10 is a graph for showing spectral sensitivity characteristics in the ultraviolet light receiving element according to the second embodiment of the present invention.

### DETAILED DESCRIPTION OF THE PREFERRED EMBODIMENTS

The invention will now be described herein with reference to illustrative embodiments.

### First Embodiment

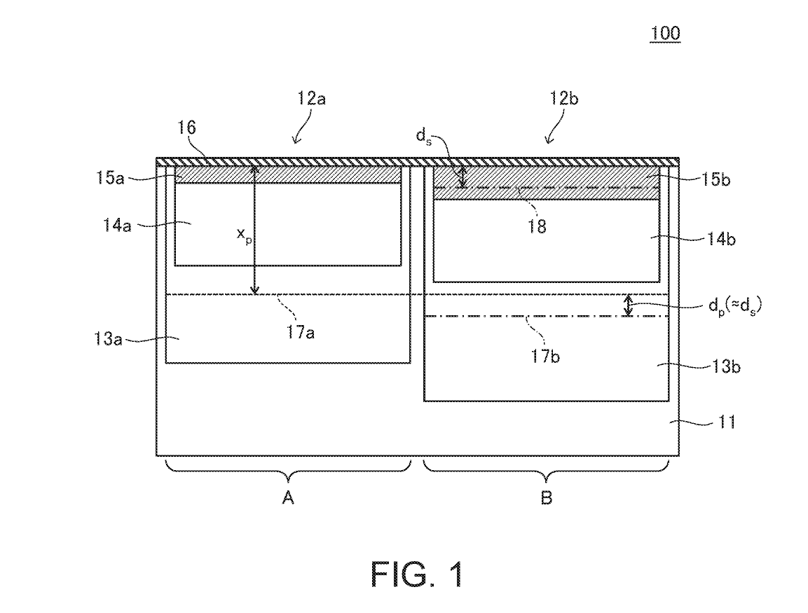

FIG. 1 is a sectional view for illustrating a configuration of an ultraviolet light receiving element 100 according to the first embodiment of the present invention.

The ultraviolet light receiving element 100 according to the first embodiment includes a photodiode 12a which is provided in a region A of an N-type semiconductor substrate 11 and which is sensitive to an ultraviolet light, a photodiode 12b which is provided in a region B of the semiconductor substrate 11 and which is insensitive to the ultraviolet light, and a thermal oxide film 16 which is formed on a surface of the semiconductor substrate 11.

The photodiode 12a includes a P-type (first conductivity-type) well implantation layer 13a, an N-type (second conductivity-type) embedded implantation layer 14a which is formed in the well implantation layer 13a, and a P-type surface implantation layer 15a which is formed in the surface of the semiconductor substrate 11 in the embedded implantation layer 14a. The surface implantation layer 15a has a peak concentration position at the topmost surface. A broken line 17a denotes a peak concentration position of the well implantation layer 13a.

The photodiode 12b includes a P-type well implantation layer 13b, an N-type embedded implantation layer 14b which is formed in the well implantation layer 13b, and a P-type surface implantation layer 15b which is formed in the surface of the semiconductor substrate 11 in the embedded implantation layer 14b. A dashed-dotted line 17b denotes a peak concentration position of the well implantation layer 13b, and a dashed-dotted line 18 denotes a peak concentration position of the surface implantation layer 15b.

In the ultraviolet light receiving element 100 according to the first embodiment, as illustrated in FIG. 1, a depth dₚ from the peak concentration position 17a of the well implantation layer 13a to the peak concentration position 17b of the well implantation layer 13b is equal to a depth dₛ from the surface of the semiconductor substrate 11 to the peak concentration position 18 of the surface implantation layer 15b.

A description is given below on a method of determining the peak concentration position 17b of the P-type well implantation layer 13b in the photodiode 12b in the ultraviolet light receiving element 100 according to the first embodiment.

The method of determining the peak concentration position 17b in the first embodiment has been obtained by taking notice that spectral characteristics in a photodiode vary depending on the position and depth-wise width of an area in which carriers generated by light absorption can be collected in the crystal of the semiconductor substrate, namely, an area sandwiched between the peak concentration position 18 of the surface implantation layer 15b and the peak concentration position 17b of the well implantation layer 13b.

When a light having an intensity Iₒ enters a surface of a light receiving element, an intensity Iₛ of the light at a depth x in a semiconductor substrate that is a constituent of the light receiving element is expressed as the following Expression (1) with the use of an absorption coefficient α which is determined by the type of the crystal used as the semiconductor and the wavelength of the light.

I_{S}≈Iₒ exp(−αx) (1)

The amount of light absorbed at the depth x in the crystal is obtained from the Expression (1), and a photocurrent I generated at that point is accordingly expressed as the following Expression (2) with the use of an elementary charge q, a wavelength λ, a light speed c, and the Planck's constant h.

$$I = \frac{q λ}{hc} {I}_{o} α exp ( - α x ) \qquad ( 2 )$$

If the sum of photocurrents generated between the surface of the semiconductor substrate 11 and a certain depth x_{d} can be taken out as an output current, the output current which is given as Iₚₕ can be expressed as the following Expression (3).

$${I}_{ph} = \frac{q λ}{hc} {I}_{o} \{ 1 - exp ( - α {x}_{d} ) \} \qquad ( 3 )$$

From the above Expressions (1) to (3), suppose that the depth from the surface of the semiconductor substrate 11 to the peak concentration position 17a of the well implantation layer 13a is given as xₚ, the depth from the surface of the semiconductor substrate 11 to the peak concentration position 18 of the surface implantation layer 15b is given as dₛ, and the depth from the peak concentration position 17a of the well implantation layer 13a to the peak concentration position 17b of the well implantation layer 13b is given as dₚ, then an output current I_{ph-HS} of the photodiode 12a and an output current I_{ph-LS} of the photodiode 12b with respect to a certain wavelength can be expressed as the following Expressions (4) and (5), respectively.

$$\begin{matrix}{I}_{ph - Hs} = \frac{q λ}{hc} = \frac{q λ}{hc} {I}_{o} \{ 1 - exp ( - α {x}_{p} ) \} & ( 4 ) \\ {I}_{ph - LS} = \frac{q λ}{hc} {I}_{o} \{ exp ( - α {d}_{s} ) - exp ( - α [ {x}_{p} + {d}_{p} ] ) \} & ( 5 )\end{matrix}$$

From the Expressions (4) and (5), an output current difference I_{ph-DIFF} between the output currents of the photodiodes 12a and 12b can be expressed as the following Expression (6).

$${I}_{ph - DIFF} = \frac{q λ}{hc} {I}_{o} \{ 1 - exp ( - α {x}_{p} ) \} - \frac{q λ}{hc} {I}_{o} \{ exp ( - α {d}_{s} ) - exp ( - α [ {x}_{p} + {d}_{p} ] ) \} \qquad ( 6 )$$

A condition under which the output current difference I_{ph-DIFF} is zero at the wavelength λ is required in order to suppress light sensitivity in the visible light range. In other words, a value of dₚ that satisfies the following Expression (7) should be obtained.

exp(−αdₚ)=1+exp(αxₚ)[exp(−αdₛ)−1] (7)

In reduction of sensitivity to the visible light included in sunlight, for example, consideration for the most intense light having the wavelength λ of longer than 500 nm is required. The absorption coefficient α of the semiconductor with respect to a light longer in wavelength than the ultraviolet light is normally low. In other words, it is regarded that αdₚ<<1 and αdₛ<<1 hold in Expression (7). When αk<<1 holds, exp(−αk) can be approximated as Expression (8).

exp(−αk)≈1−αk (8)

Expression (9) can accordingly be obtained from Expression (7) and Expression (8).

dₚ≈dₛ exp(αxₚ) (9)

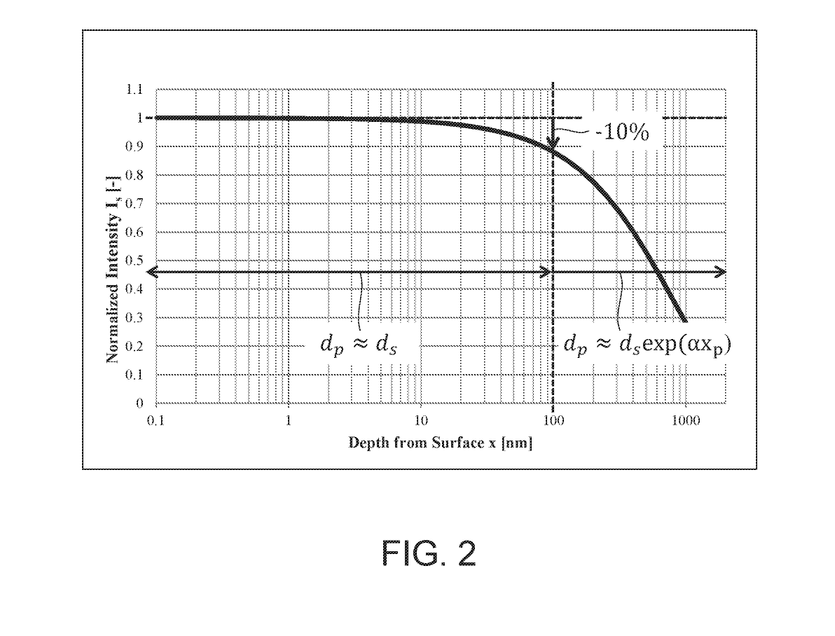

As described above, in reduction of sensitivity to the visible light included in sunlight, consideration for a light having the wavelength λ of longer than 500 nm is required. The absorption coefficient α of, for example, a single-crystal silicon substrate used as the semiconductor substrate 11 is 1.11 E+06 [1/m] with respect to a light having a wavelength of 500 nm. A relation observed in this case between the depth x in the single-crystal silicon substrate and the intensity Iₛ of the light is shown in FIG. 2 in the form of graph in accordance with Expression (1).

When single-crystal silicon is used, the light having a wavelength of 500 nm has an absorption coefficient of about 1/100 compared with the ultraviolet light having a shorter wavelength, and, as can be seen in FIG. 2, since the intensity of the light attenuates little in a shallow region of the single-crystal silicon substrate, the intensity of the light having a wavelength of 500 nm does not vary much depending on depth. In a region in which the depth x is less than 100 nm, in particular, the intensity Iₛ of the light changes only by 10% or so, and it can be regarded that the intensity Iₛ of the light hardly attenuates in the region.

Accordingly, in FIG. 2, the depth xₚ is less than 100 nm in a region where it can be regarded that the intensity Iₛ of the light hardly attenuates, and αxₚ<<1 holds in the above Expression (9). That is, αxₚ can be regarded as zero in the Expression (9). Thus, by forming the ultraviolet light receiving element 100 so as to make dₚ and dₛ an equal value, the photodiode 12a and the photodiode 12b can be given equal sensitivity in the visible light range. In other words, the difference in output current between the photodiode 12a and the photodiode 12b can be reduced.

As described above, in the ultraviolet light receiving element 100 according to the first embodiment, the depth dₛ from the surface of the semiconductor substrate 11 to the peak concentration position 18 of the surface implantation layer 15b and the depth dₚ from the peak concentration position 17a of the well implantation layer 13a to the peak concentration position 17b of the well implantation layer 13b are set equal to each other as illustrated in FIG. 1. The ultraviolet light receiving element 100 reduced in spectral sensitivity in the visible light range can thus be obtained.

A method of manufacturing the ultraviolet light receiving element 100 according to the first embodiment is described next.

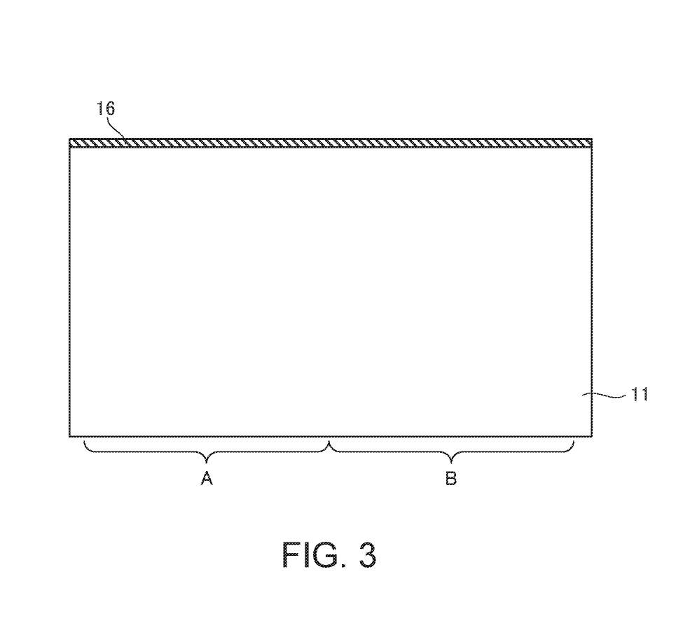

FIG. 3 to FIG. 5 are sectional views for illustrating manufacturing steps in the method of manufacturing the ultraviolet light receiving element 100 according to the first embodiment.

First, as illustrated in FIG. 3, thermal oxidation is performed on the semiconductor substrate 11 to form the thermal oxide film 16 on the surface of the semiconductor substrate 11. A preferred thickness of the thermal oxide film 16 is from approximately 6 nm to approximately 10 nm.

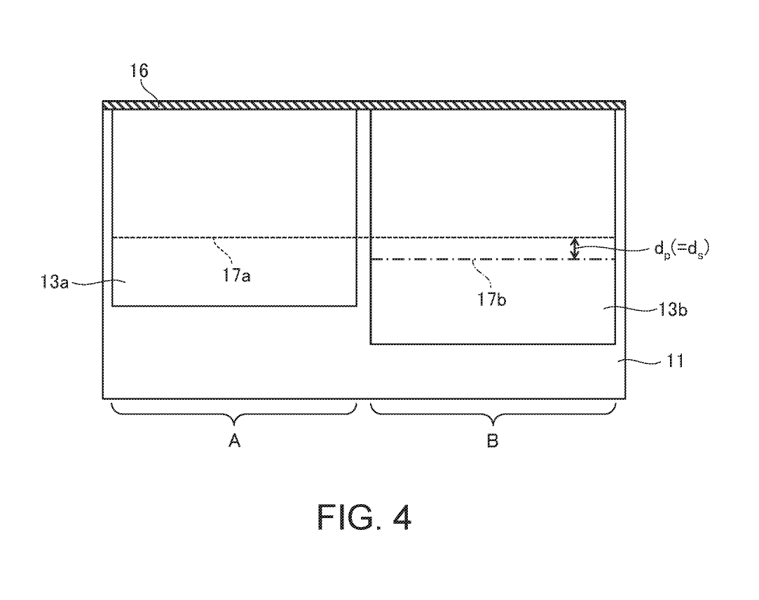

Next, as illustrated in FIG. 4, the well implantation layer 13a and the well implantation layer 13b are formed by performing ion implantation selectively in each of the region A and the region B and implanting BF₂⁺ as P-type impurities.

In this step, the implantation energy and the implantation impurity dose are set so that the depth dₚ from the peak concentration position 17a of the well implantation layer 13a to the peak concentration position 17b of the well implantation layer 13b is equal to a predetermined value of the depth dₛ from the surface of the semiconductor substrate 11 to the peak concentration position 18 of the surface implantation layer 15b (see FIG. 1). For instance, the implantation energy for forming the well implantation layer 13a is set to 100 keV, the implantation energy for forming the well implantation layer 13b is set to 120 keV, and the implanted impurity dose is set to 5.0 E12 [ions/cm²] for each of the well implantation layers 13a and 13b.

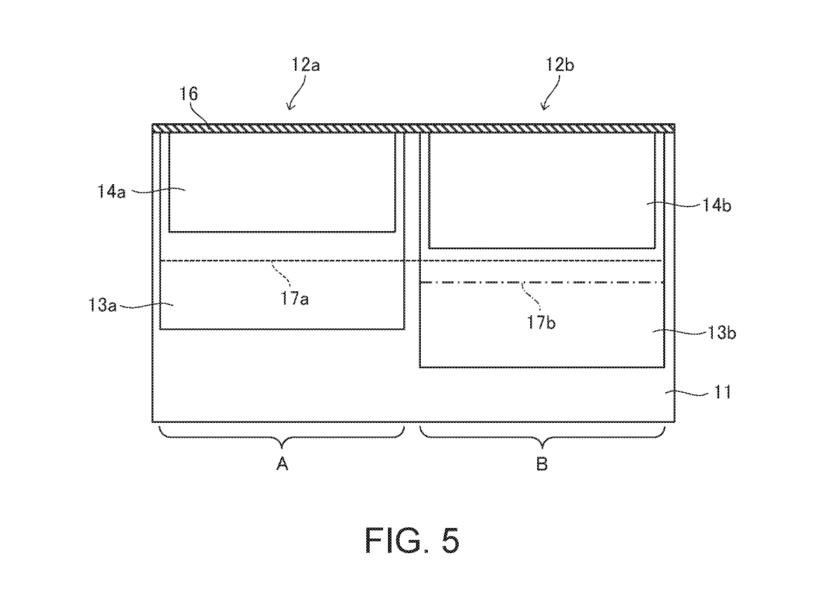

Next, as illustrated in FIG. 5, the embedded implantation layer 14a and the embedded implantation layer 14b are formed by selective ion implantation of As⁺ in each of the well implantation layer 13a and the well implantation layer 13b as N-type impurities.

In this step, the implantation energy for forming the embedded implantation layer 14a and the implantation energy for forming the embedded implantation layer 14b are both set to, for example, 40 keV, and the implanted impurity dose is set to, for example, 1.0 E13 [ions/cm²], for each of the embedded implantation layers 14a and 14b.

The semiconductor substrate 11 is then annealed to electrically activate the implanted impurities. Rapid thermal annealing (RTA) is conducted here at 950° C. for 1 second in order to suppress the diffusion of the implanted impurities.

Next, as illustrated in FIG. 1, the surface implantation layer 15a and the surface implantation layer 15b are formed by selective ion implantation of BF₂⁺ in each of the embedded implantation layer 14a and the embedded implantation layer 14b as P-type impurities. The surface implantation layer 15b is formed so that the depth dₛ from the surface of the semiconductor substrate 11 to the peak concentration position 18 of the surface implantation layer 15b is equal to the predetermined depth described above, namely, the depth dₚ.

The ion implantation energy and the implanted impurity dose in this step are set to, for example, 1 keV and 1.5 E14 [ions/cm²], respectively, to form the surface implantation layer 15a, and to 10 keV and 9.0 E13 [ions/cm²], respectively, to form the surface implantation layer 15b.

The semiconductor substrate 11 is then subjected to RTA at a high temperature for a short time (e.g., at 1,000° C. for 1 second) to electrically activate the impurities in the surface implantation layer 15a and the surface implantation layer 15b.

The ultraviolet light receiving element 100 according to the first embodiment which is illustrated in FIG. 1 is manufactured in the manner described above.

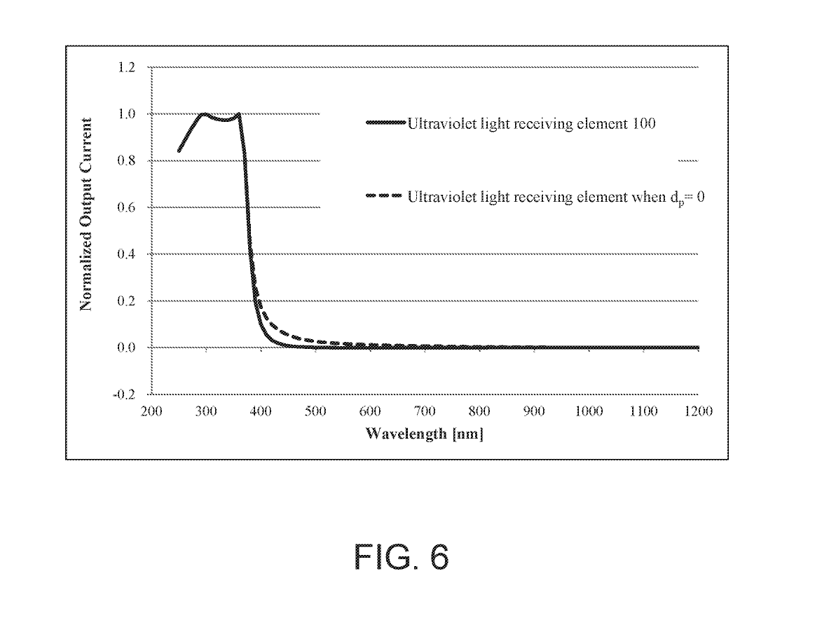

The spectral sensitivity characteristics of the ultraviolet light receiving element 100 which is formed by the manufacturing method described above and the spectral sensitivity characteristics of the ultraviolet light receiving element in which the depth dₚ from the peak concentration position 17a of the well implantation layer 13a to the peak concentration position 17b of the well implantation layer 13b is set to zero, that is, in which the peak concentration position 17a of the well implantation layer 13a and the peak concentration position 17b of the well implantation layer 13b are set to the same depth are shown in FIG. 6. As seen in FIG. 6, in the spectral sensitivity characteristics of the ultraviolet light receiving element when dₚ is zero, sensitivity remains around a wavelength exceeding 450 nm. In the spectral sensitivity characteristics of the ultraviolet light receiving element 100 formed so as to set dₚ and dₛ to the same value, on the other hand, sensitivity is substantially zero in a range where a wavelength of 450 nm or longer. The ultraviolet light receiving element 100 according to the first embodiment can thus have spectral sensitivity characteristics that provide sensitivity to the light in the ultraviolet range and that keep visible light sensitivity low.

### Second Embodiment

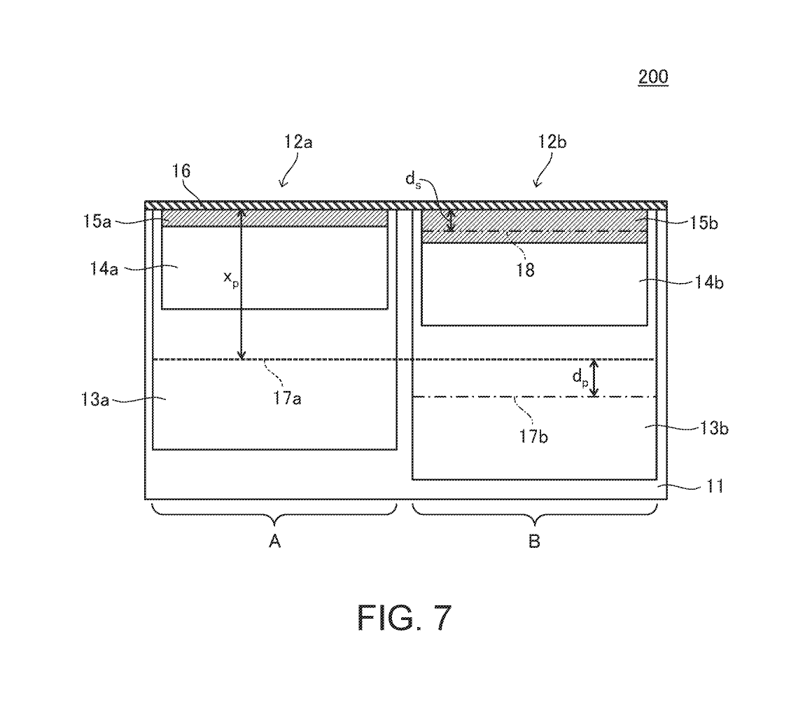

FIG. 7 is a sectional view for illustrating the configuration of an ultraviolet light receiving element 200 according to the second embodiment of the present invention. Components that are the same as those of the ultraviolet light receiving element 100 according to the first embodiment which is illustrated in FIG. 1 are denoted by the same reference numerals, and redundant descriptions are omitted as appropriate.

A main difference between the ultraviolet light receiving element 200 according to the second embodiment and the ultraviolet light receiving element 100 according to the first embodiment is that the depth dₛ from the surface of the semiconductor substrate 11 to the peak concentration position 18 of the surface implantation layer 15b and the depth dₚ from the peak concentration position 17a of the well implantation layer 13a to the peak concentration position 17b of the well implantation layer 13b differ from each other.

A description is given below on a method of determining the peak concentration position 17b in the P-type well implantation layer 13b of the photodiode 12b in the ultraviolet light receiving element 200 according to the second embodiment.

The method of determining the peak concentration position 17b in the second embodiment has also been obtained in the same manner as in the first embodiment by taking notice that spectral characteristics in a photodiode vary depending on the position and depth-wise width of an area in which carriers generated by light absorption can be collected in the crystal of the semiconductor substrate.

In order to consider a light having the wavelength λ of longer than 500 nm similar to the first embodiment, FIG. 2 is referred to again in which a graph in accordance with the above Expression (1) is shown. FIG. 2 shows the relation observed between the depth x in a single-crystal silicon substrate that is the semiconductor substrate 11 and the intensity Iₛ of the light, when a single-crystal silicon substrate having the absorption coefficient α of 1.11 E+06 [1/m] with respect to a light having a wavelength of 500 nm is used as the semiconductor substrate 11.

As described above, the intensity of the light attenuates little in a shallow region of the single-crystal silicon substrate, and accordingly does not vary much depending on depth. In particular, the intensity Iₛ of the light in a region in which the depth x is less than 100 nm changes only by 10% or so, and it can be regarded that the intensity Iₛ of the light is substantially constant in the region.

When the depth x exceeds 100 nm, on the other hand, the light having a wavelength of 500 nm attenuates in intensity to 90% or less of the incident light. From then on, the intensity of the light attenuates more as the depth increases.

Accordingly, because in the region in FIG. 2 where the intensity Iₛ of the light attenuates considerably, the depth Xₚ exceeds 100 nm, inequality αXₚ<<1 does not hold in the above Expression (9), that is, αxₚ cannot be regarded as zero in the Expression (9).

For that reason, the ultraviolet light receiving element 200 according to the second embodiment is formed with the use of dₚ that can be obtained from the above Expression (9). In this manner, the photodiode 12a and the photodiode 12b can be given equal sensitivity in the visible light range. In other words, the difference in output current between the photodiode 12a and the photodiode 12b can be reduced in the visible light range.

In the second embodiment, the depth dₚ from the peak concentration position 17a of the well implantation layer 13a to the peak concentration position 17b of the well implantation layer 13b is determined in a manner described below, for example.

To give a specific example, suppose that the depth dₛ from the surface of the semiconductor substrate 11 to the peak concentration position 18 of the surface implantation layer 15b is 50 nm, the depth Xₚ from the surface of the semiconductor substrate 11 to the peak concentration position 17a of the well implantation layer 13a is 400 nm, and that a single-crystal silicon substrate having the absorption coefficient α of 1.11 E+06 [1/m] with respect to a light having a wavelength of 500 nm is used as the semiconductor substrate 11, the depth dₚ is then calculated as 78 nm by the above Expression (9). In this case, the ultraviolet light receiving element 200 reduced in spectral sensitivity in the visible light range can accordingly be obtained by setting the depth dₚ equal to 78 nm from the peak concentration position 17a of the well implantation layer 13a to the peak concentration position 17b of the well implantation layer 13b.

A method of manufacturing the ultraviolet light receiving element 200 according to the second embodiment is described next.

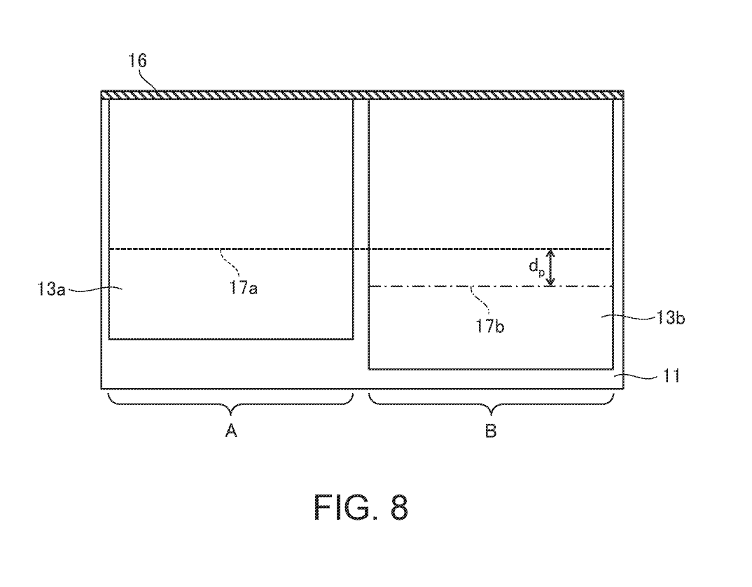

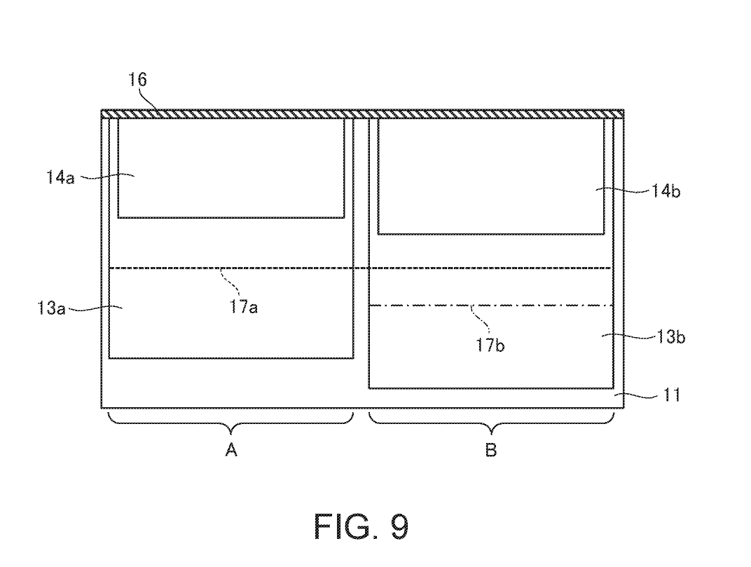

FIG. 8 and FIG. 9 are sectional views for illustrating manufacturing steps in the method of manufacturing the ultraviolet light receiving element 200 according to the second embodiment. The following description is about the method of manufacturing the ultraviolet light receiving element 200 of the specific example given above, in which a single-crystal silicon substrate having the absorption coefficient α of 1.11 E+06 [1/m] with respect to the light having a wavelength of 500 nm is used as the semiconductor substrate 11, the depth dₛ from the surface of the semiconductor substrate 11 to the peak concentration position 18 of the surface implantation layer 15b is 50 nm, the depth Xₚ from the surface of the semiconductor substrate 11 to the peak concentration position 17a of the well implantation layer 13a is 400 nm, and the depth dₚ from the peak concentration position 17a of the well implantation layer 13a to the peak concentration position 17b of the well implantation layer 13b is 78 nm.

First, as illustrated in FIG. 3, thermal oxidation is performed on the semiconductor substrate 11 to form the thermal oxide film 16 on the surface of the semiconductor substrate 11, similar to the method of manufacturing the ultraviolet light receiving element 100 according to the first embodiment. A preferred thickness of the thermal oxide film 16 is from approximately 6 nm to approximately 10 nm.

Next, as illustrated in FIG. 8, the well implantation layer 13a and the well implantation layer 13b are formed by performing ion implantation selectively in each of the region A and the region B and implanting B⁺ as P-type impurities.

The implantation energy and the implanted impurity dose in this step are set so that the depth dₚ from the peak concentration position 17a of the well implantation layer 13a to the peak concentration position 17b of the well implantation layer 13b is a depth calculated by the above Expression (9), in this example, 78 nm. In this example, the implantation energy for forming the well implantation layer 13a is set to 110 keV, the implantation energy for forming the well implantation layer 13b is set to 120 keV, and the implanted impurity dose is set to 5.0 E12 [ions/cm²] for each of the well implantation layers 13a and 13b.

Next, as illustrated in FIG. 9, the embedded implantation layer 14a and the embedded implantation layer 14b are formed by selectively implanting P⁺ as N-type impurities in each of the well implantation layer 13a and the well implantation layer 13b through ion implantation.

In this example, the implantation energy for forming the embedded implantation layer 14a is set to 36 keV, the implantation energy for forming the embedded implantation layer 14b is set to 120 keV, and the implanted impurity dose is set to 9.0 E12 [ions/cm²] for each of the embedded implantation layers 14a and 14b.

The semiconductor substrate 11 is then annealed to electrically activate the implanted impurities. RTA is conducted here at 950° C. for 5 seconds in order to suppress the diffusion of the implanted impurities.

Next, as illustrated in FIG. 7, the surface implantation layer 15a and the surface implantation layer 15b are formed by selectively implanting BF₂⁺ as P-type impurities in each of the embedded implantation layer 14a and the embedded implantation layer 14b through ion implantation. In this example, the surface implantation layer 15b is formed so that the depth dₛ from the surface of the semiconductor substrate 11 to the peak concentration position 18 of the surface implantation layer 15b is 50 nm.

The ion implantation energy and the implanted impurity dose in this example are set to 8 keV and 5.0 E13 [ions/cm²], respectively, to form the surface implantation layer 15a, and to 35 keV and 4.5 E13 [ions/cm²], respectively, to form the surface implantation layer 15b.

The semiconductor substrate 11 is then subjected to RTA at a high temperature for a short time (e.g., at 1,000° C. for 1 second) to electrically activate the impurities in the surface implantation layer 15a and the surface implantation layer 15b.

The ultraviolet light receiving element 200 according to the second embodiment which is illustrated in FIG. 7 is manufactured in the manner described above.

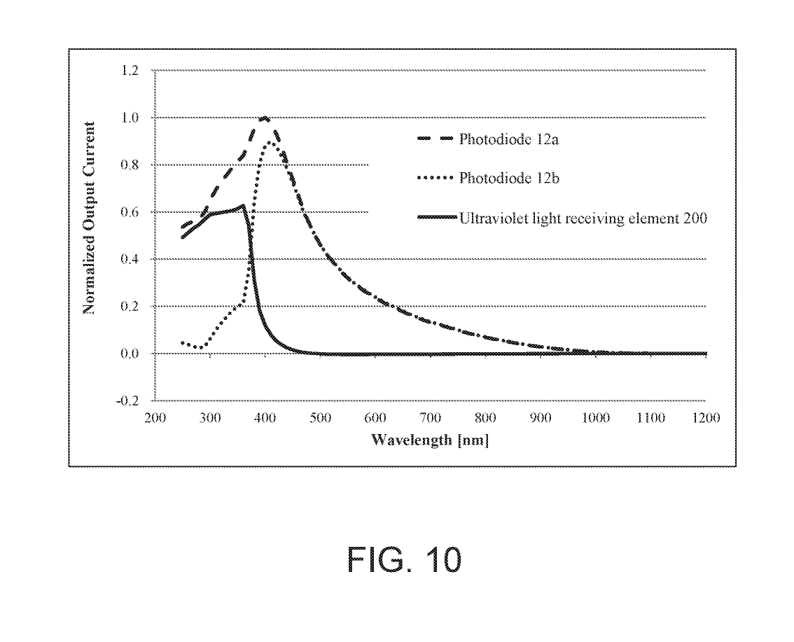

FIG. 10 is a graph for showing the spectral sensitivity characteristics of the ultraviolet light receiving element 200 that is obtained by the method of manufacturing the ultraviolet light receiving element 200 described as a specific example of the second embodiment. It is understood from FIG. 10 that the output current of the photodiode 12a and the output current of the photodiode 12b become a substantial match to each other in a range where a wavelength of approximately 450 nm or higher. The ultraviolet light receiving element 200 according to the second embodiment can thus have spectral sensitivity characteristics that provide sensitivity to a light in the ultraviolet range and that keep visible light sensitivity low by calculating the difference between the output currents of the photodiode 12a and the photodiode 12b.

It is apparent that the present invention is not limited to the above embodiments, but may be modified and changed without departing from the scope and spirit of the invention.

For instance, a shallow region near a surface of the surface implantation layer 15b of the photodiode 12b which is insensitive to the ultraviolet light in the embodiments described above may be provided with a surface implantation layer having a conductivity type opposite to the conductivity type of the surface implantation layer 15b to effectively nullify a current generated by the ultraviolet light, as described in Y. R. Sipauba Carvalho da Silva, et al., “An Ultraviolet Radiation Sensor Using Differential Spectral Response of Silicon Photodiodes”, 2015 IEEE SENSORS, pp. 1-4.

While an example in which a single crystal silicon substrate is used as a semiconductor substrate has been described in the embodiments described above, but the present invention is not limited to this, and other semiconductor substrates such as a GaAs substrate can also be used, for example.

While the first conductivity type is the P type and the second conductivity type is the N type in the embodiments described above, the conductivity types may be switched so that the first conductivity type is the N type and the second conductivity type is the P type.

What is claimed is:

1. An ultraviolet light receiving element, comprising:
a first photodiode sensitive to an ultraviolet light provided in a first region of a semiconductor substrate, and including a first well implantation layer of a first conductivity type, a first embedded implantation layer of a second conductivity type, and a first surface implantation layer of the first conductivity type, the first embedded implantation layer being formed in the first well implantation layer, the first surface implantation layer being formed in a surface of the semiconductor substrate in the first embedded implantation layer; and
a second photodiode insensitive to an ultraviolet light provided in a second region of the semiconductor substrate, and including a second well implantation layer of the first conductivity type, a second embedded implantation layer of the second conductivity type, and a second surface implantation layer of the first conductivity type, the second embedded implantation layer being formed in the second well implantation layer, the second surface implantation layer being formed in the surface of the semiconductor substrate in the second embedded implantation layer,
the second well implantation layer having a peak concentration position deeper than a peak concentration position of the first well implantation layer by a depth equal to a depth from the surface of the semiconductor substrate to a peak concentration position of the second surface implantation layer.

2. An ultraviolet light receiving element, comprising:
a first photodiode sensitive to the ultraviolet light provided in a first region of a semiconductor substrate, and including a first well implantation layer of a first conductivity type, a first embedded implantation layer of a second conductivity type, and a first surface implantation layer of the first conductivity type, the first embedded implantation layer being formed in the first well implantation layer, the first surface implantation layer being formed in a surface of the semiconductor substrate in the first embedded implantation layer; and
a second photodiode insensitive to the ultraviolet light provided in a second region of the semiconductor substrate, and including a second well implantation layer of the first conductivity type, a second embedded implantation layer of the second conductivity type, and a second surface implantation layer of the first conductivity type, the second embedded implantation layer being formed in the second well implantation layer, the second surface implantation layer being formed in the surface of the semiconductor substrate in the second embedded implantation layer,
the second well implantation layer having a peak concentration position deeper than the peak concentration position of the first well implantation layer by a depth dₚ which is calculated by the following expression:
dₚ≈dₛ exp(αxₚ)
where dₛ is a depth from the surface of the semiconductor substrate to a peak concentration position of the second surface implantation layer, xₚ is a depth from the surface of the semiconductor substrate to a peak concentration position of the first well implantation layer, α is a light absorption coefficient in the semiconductor substrate, and αxₚ is not regarded as zero.

3. A method of manufacturing an ultraviolet light receiving element, comprising:
forming, in a first region of a semiconductor substrate of a first conductivity type, a first photodiode sensitive to the ultraviolet light including a first well implantation layer of a second conductivity type, a first embedded implantation layer of the first conductivity type, and a first surface implantation layer of the second conductivity type, the first embedded implantation layer being formed in the first well implantation layer, the first surface implantation layer being formed in a surface of the semiconductor substrate in the first embedded implantation layer; and
forming, in a second region of the semiconductor substrate, a second photodiode insensitive to the ultraviolet light including a second well implantation layer of the second conductivity type, a second embedded implantation layer of the first conductivity type, and a second surface implantation layer of the second conductivity type, the second embedded implantation layer being formed in the second well implantation layer, the second surface implantation layer being formed in the surface of the semiconductor substrate in the second embedded implantation layer,
the second well implantation layer being formed so as to have a peak concentration position deeper than a peak concentration position of the first well implantation layer by a depth equal to a depth from the surface of the semiconductor substrate to a peak concentration position of the second surface implantation layer.

4. A method of manufacturing an ultraviolet light receiving element, comprising:
forming, in a first region of a semiconductor substrate of a first conductivity type, a first photodiode sensitive to an ultraviolet light including a first well implantation layer of a second conductivity type, a first embedded implantation layer of the first conductivity type, and a first surface implantation layer of the second conductivity type, the first embedded implantation layer being formed in the first well implantation layer, the first surface implantation layer being formed in a surface of the semiconductor substrate in the first embedded implantation layer; and
forming, in a second region of the semiconductor substrate, a second photodiode insensitive to the ultraviolet light including a second well implantation layer of the second conductivity type, a second embedded implantation layer of the first conductivity type, and a second surface implantation layer of the second conductivity type, the second embedded implantation layer being formed in the second well implantation layer, the second surface implantation layer being formed in the surface of the semiconductor substrate in the second embedded implantation layer,
the second well implantation layer being formed so as to have a peak concentration position deeper than the peak concentration position of the first well implantation layer by a depth dₚ which is calculated by the following expression:
dₚ≈dₛ exp(αx ₚ)
where dₛ is a depth from the surface of the semiconductor substrate to a peak concentration position of the second surface implantation layer, xₚ is a depth from the surface of the semiconductor substrate to a peak concentration position of the first well implantation layer, α is a light absorption coefficient in the semiconductor substrate, and αxₚ is not regarded as zero.
